(19) United States
(12) Patent Application Publication
(10) Pub. No.: US 2025/0301638 A1
(43) Pub. Date: Sep. 25, 2025

(54) MAGNETIC MEMORY DEVICE

(71) Applicant: Samsung Electronics Co., Ltd., Suwon-si (KR)

(72) Inventors: Dae Shik KIM, Suwon-si (KR); Bo Young SEO, Suwon-si (KR)

(73) Assignee: Samsung Electronics Co., Ltd., Suwon-si (KR)

(21) Appl. No.: 19/002,253

(22) Filed: Dec. 26, 2024

(30) Foreign Application Priority Data
Mar. 25, 2024 (KR) 10-2024-0040418
Apr. 25, 2024 (KR) 10-2024-0055509

(51) Int. Cl. H10B 20/25; H10B 61/00

(52) U.S. Cl. CPC H10B 20/25; H10B 61/10

(57) ABSTRACT

A magnetic memory device includes a substrate; and a memory unit cell array, which includes a memory unit cell and a one-time-programmable (OTP) unit cell, on the substrate. The memory unit cell includes a first magnetic tunnel junction element on the substrate, and a wiring structure connecting the substrate with the first magnetic tunnel junction element. The OTP unit cell includes a connection wiring on the substrate, a second magnetic tunnel junction element and a third magnetic tunnel junction element, which are spaced apart from each other on the connection wiring, a first lower wiring structure and a second lower wiring structure, which connects the substrate with the connection wiring, spaced apart from each other, and a first upper wiring structure connecting the connection wiring with the second magnetic tunnel junction element.

### CROSS-REFERENCE TO RELATED APPLICATION

This application claims priority from Korean Patent Application No. 10-2024-0040418 filed on Mar. 25, 2024, and Korean Patent Application No. 10-2024-0055509 filed on Apr. 25, 2024 in the Korean Intellectual Property Office and all the benefits accruing therefrom under 35 U.S.C. 119, the contents of which in its entirety are herein incorporated by reference.

### BACKGROUND

### Technical Field

The present disclosure relates to a magnetic memory device.

### Description of the Related Art

With high-speed and low-power of electronic devices, a memory device embedded in an electronic device requires fast read/write operations and low operating voltages. A magnetic memory device has been studied as a memory device that satisfies such requirements. The magnetic memory device is non-volatile and enables high-speed operation and thus has been spotlighted as a next-generation memory.

As a magnetic memory device is increasingly highly integrated, STT-MRAM for storing information using a spin transfer torque (STT) phenomenon is being studied. The STT-MRAM may induce a magnetization reversal by applying a direct current to a magnetic tunnel junction element to store information. The highly integrated STT-MRAM requires high-speed operation and low current operation.

Meanwhile, one-time-programmable (OTP) memory is a nonvolatile memory in which data is permanently maintained in a single program. The OTP generally aims to record specific information only once and read it continuously, and is widely used in the field of applications where stability and security of data are important. Since the OTP can be programmed only once, its information cannot be changed, thereby making sure of integrity and stability of data. The OTP is mainly used in applications that require reliability and security. For example, the OTP is used to store information such as digital security tokens, smart cards, keys and passwords, boot codes, and production/manufacturing settings, and may be embedded as a portion of a semiconductor chip or provided as an independent chip. When the OTP is embedded as a portion of a chip and is fully compatible with a logic CMOS process, the OTP may be implemented and usefully used at low cost without affecting performance of a core logic.

### BRIEF SUMMARY

An object of the present disclosure is to provide a magnetic memory device in which product reliability is improved.

The objects of the present disclosure are not limited to those mentioned above and additional objects of the present disclosure, which are not mentioned herein, will be clearly understood by those skilled in the art from the following description of the present disclosure.

According to an example embodiment of the present disclosure, a magnetic memory device includes a substrate; and a memory cell array, which includes a memory unit cell and one-time-programmable (OTP) unit cell, on the substrate. The memory unit cell includes a first magnetic tunnel junction element on the substrate, and a wiring structure connecting the substrate with the first magnetic tunnel junction element. The OTP unit cell includes a connection wiring on the substrate, a second magnetic tunnel junction element and a third magnetic tunnel junction element, which are spaced apart from each other on the connection wiring, a first lower wiring structure and a second lower wiring structure, which connects the substrate with the connection wiring and spaced apart from each other, and a first upper wiring structure connecting the connection wiring with the second magnetic tunnel junction element.

According to an example embodiment of the present disclosure, a magnetic memory device includes a memory unit cell including a first magnetic tunnel junction element connected to a first bit line and a first cell transistor connecting the first magnetic tunnel junction element with a first source line; and a one-time-programmable (OTP) unit cell including second to fourth magnetic tunnel junction elements connected to a second bit line and second to fourth cell transistors connecting a second source line with the second magnetic tunnel junction element. The third and fourth magnetic tunnel junction elements are not connected to the second to fourth cell transistors.

According to an example embodiment of the present disclosure, a magnetic memory device includes a plurality of memory unit cells connected between a first bit line and a first source line; a plurality of one-time-programmable (OTP) unit cells connected between a second bit line and a second source line; and a peripheral circuit connected to the plurality of memory unit cells and the plurality of OTP unit cells. Each of the plurality of memory unit cells includes a first magnetic tunnel junction element connected to the first bit line and a first cell transistor connecting the first magnetic tunnel junction element with the first source line. Each of the plurality of OTP unit cells includes second to fourth magnetic tunnel junction elements connected to the second bit line and second to fourth cell transistors connecting the second source line with the second magnetic tunnel junction element. The third and fourth magnetic tunnel junction elements are not connected to the second to fourth cell transistors.

According to an example embodiment of the present disclosure, a magnetic memory device includes a substrate; and a memory unit cell array, which includes a memory unit cell and a one-time-programmable (OTP) unit cell, on the substrate. The memory unit cell includes a first transistor on the substrate and a first magnetic tunnel junction element on the first transistor, and a wiring structure connecting the first magnetic tunnel junction element with the first transistor. The OTP unit cell includes a second transistor on the substrate and a second magnetic tunnel junction element on the second transistor, a third transistor on the substrate and a third magnetic tunnel junction element on the third transistor, and a first wiring structure connecting the second magnetic tunnel junction element to the second and third transistors. One of magnetic patterns of the third magnetic tunnel junction element facing the substrate is electrically floating.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an exemplary block diagram of a magnetic memory device according to some embodiments;

FIG. 2 is an exemplary circuit diagram illustrating a magnetic memory device according to some embodiments;

FIGS. 3 and 4 are exemplary cross-sectional views of a magnetic memory device according to some embodiments;

FIG. 5 is an exemplary cross-sectional view of a magnetic memory device according to some embodiments;

FIG. 6 is an exemplary cross-sectional view of a magnetic memory device according to some embodiments;

FIG. 7 is an exemplary cross-sectional view of a magnetic memory device according to some embodiments;

FIG. 8 is an enlarged view of a region S1 of FIG. 3;

FIG. 9 is an enlarged view of a region S2 of FIGS. 4 to 7;

FIG. 10 is an enlarged view of a region S3 of FIG. 3;

FIG. 11 is an enlarged view of a region S4 of FIGS. 4 to 7;

FIG. 12 is an exemplary circuit diagram illustrating a magnetic memory device according to some embodiments;

FIG. 13 is an exemplary circuit diagram illustrating a magnetic memory device according to some embodiments;

FIG. 14 is an exemplary circuit diagram illustrating a magnetic memory device according to some embodiments; and

FIG. 15 is an exemplary circuit diagram illustrating a magnetic memory device according to some embodiments.

### DETAILED DESCRIPTION OF THE DISCLOSURE

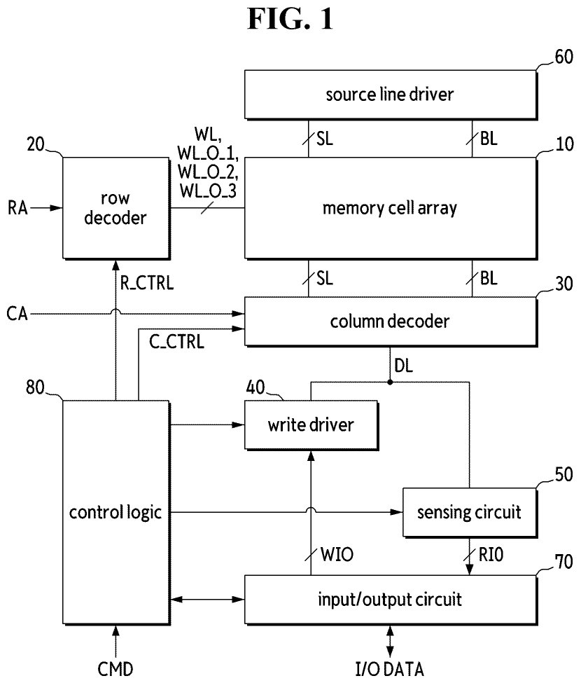

FIG. 1 is an exemplary block view of a magnetic memory device according to some embodiments.

Referring to FIG. 1, the magnetic memory device according to some embodiments may include a memory cell array 10, a row decoder 20, a column decoder 30, a write driver 40, a sensing circuit 50, a source line driver 60, an input/output circuit 70 and a control logic 80.

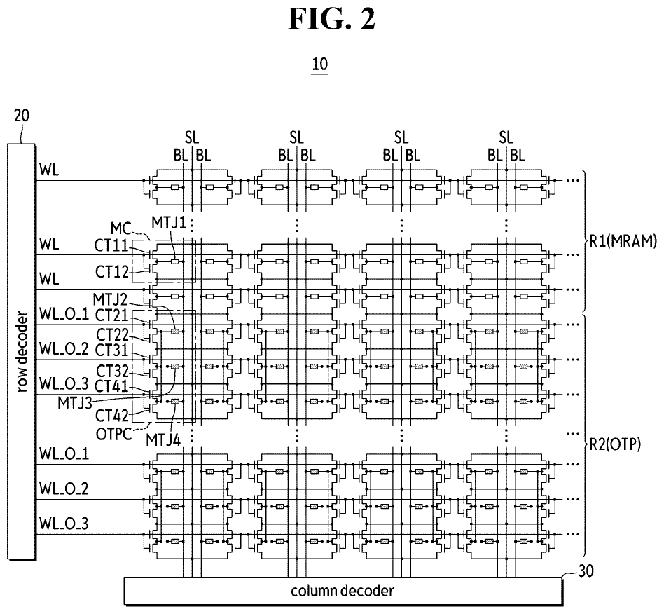

The memory cell array 10 may include a plurality of word lines WL, WL_O_1, WL_O_2, WL_O_3, a plurality of bit lines BL, and a plurality of source lines SL. Memory cells (e.g., a memory unit cell MC and an OTP unit cell (OTPC) of FIG. 2) may be connected to points where word lines WL, WL_O_1, WL_O_2 and WL_O_3 cross the bit line BL. Each of the memory cells may be configured to store data. The memory cell may include, for example, a variable resistance element, of which a value of stored data is determined depending on a resistance value, for example, a magnetic tunnel junction (MTJ) element.

For example, the memory cell may include a Resistive RAM (ReRAM), a Phase Change Random Access Memory (PRAM), a Ferroelectric Random Access Memory (FRAM), and may also include a Magnetic Random Access Memory (MRAM) such as a Spin-Transfer Torque Magnetic Random Access Memory (STT-MRAM), a Spin Torque Transfer Magnetization Switching RAM (Spin-RAM) and a Spin Momentum Transfer RAM (SMT-RAM).

The row decoder 20 may select (or drive) the word lines WL, WL_O_1, WL_O_2 and WL_O_3 connected to the memory cell in which a read operation or a program operation is performed, based on a row address RA and a row control signal R_CTRL. The row decoder 20 may provide a driving voltage received from the control logic 80 to the selected word line.

The column decoder 30 may select a bit line BL and/or a source line SL, which is connected to the memory cell in which a read operation or a program operation is performed, based on a column address CA and a column control signal C_CTRL. The column decoder 30 may connect the selected bit line BL and the selected source line SL to a data line DL.

The write driver 40 may drive a program voltage (or a write current) for storing write data in the memory cell selected by the row decoder 20 and the column decoder 30 during the program operation. For example, during the program operation, the write driver 40 may control a voltage of the data line DL based on write data I/O DATA input from the input/output circuit 70 through a write input/output line WIO to store the write data I/O DATA in the selected memory cell.

The sensing circuit 50 may determine a value of data stored in the memory cell by sensing a signal output through the data line DL during the read operation. The sensing circuit 50 may be connected to the column decoder 30 through the data line DL, and may be connected to the input/output circuit 70 through a read input/output line RIO. The sensing circuit 50 may input the sensed read data I/O DATA to the input/output circuit 70 through the read input/output line RIO.

The source line driver 60 may drive the source line SL at a specific voltage level under the control of the control logic 80. For example, the source line driver 60 may receive a voltage for driving the source line SL from the control logic 80

The input/output circuit 70 may transfer the write data I/O DATA input from the outside to the write driver 40 and output the read data I/O DATA input from the sensing circuit 50 to the outside.

The control logic 80 may control the overall operation of the magnetic memory device. For example, the control logic 80 may control the row decoder 20, the column decoder 30, the write driver 40, the sensing circuit 50, the source line driver 60, the input/output circuit 70 and the like. Meanwhile, the control logic 80 may operate in response to a command CMD or control signals, which is (are) input from the outside. The command CMD may include a read command, a write command and the like.

FIG. 2 is an exemplary circuit diagram illustrating a magnetic memory device according to some embodiments.

Referring to FIG. 2, in some embodiments, a memory cell array 10 includes a plurality of memory cells MC and OTPC arranged along a row direction and a column direction. The plurality of memory cells MC and OTPC include a plurality of memory unit cells MC and a plurality of OTP unit cells OTPC.

The plurality of memory unit cells MC may be connected to first word lines WL, the bit lines BL and the source lines SL. Each memory unit cell MC may include a first magnetic tunnel junction element MTJ1 and first cell transistors CT11 and CT12.

The memory unit cell MC can be programmed multiple times. The memory unit cell MC may be switched to two resistance states by an electrical pulse applied to the first magnetic tunnel junction element MTJ1. The memory unit cell MC may be used as an MRAM.

In some embodiments, the memory unit cell MC may have a structure in which the ell transistors CT11 and CT12 are connected to one magnetic tunnel junction element MTJ1. For example, the memory unit cell MC may include two cell transistors CT11 and CT12. The number of cell transistors included in the memory unit cell MC is not limited thereto and may vary.

One end of the first magnetic tunnel junction element MTJ1 is connected to the bit line BL, and the other end of the first magnetic tunnel junction element MTJ1 is connected to one end of the (1-1)th cell transistor CT11 and one end of the (1-2)th cell transistor CT12. The other end of the (1-1)th cell transistor CT11 and the other end of the (1-2)th cell transistor CT12 are connected to the source line SL. A gate electrode of the (1-1)th cell transistor CT11 and a gate electrode of the (1-2)th cell transistor CT12 may be connected to the first word line WL. The (1-1)th cell transistor CT11 and the (1-2)th cell transistor CT12 may be turned on or off by a signal (or voltage) provided through the first word line WL.

The plurality of OTP unit cells OTPC may be connected to the second to fourth word lines WL_O_1, WL_O_2 and WL_O_3, the bit lines BL and the source lines SL. Each of the OTP unit cells OTPC may include a second magnetic tunnel junction element MTJ2, second cell transistors CT21 and CT22, a third magnetic tunnel junction element MTJ3, third cell transistors CT31 and CT32, a fourth magnetic tunnel junction element MTJ4, and fourth cell transistors CT41 and CT42.

The OTP unit cell OTPC can be programmed only once. The programmed second magnetic tunnel junction element MTJ2 may have an irreversible resistance state. The OTP unit cell OTPC may be used as an OTP.

The OTP unit cell OTPC according to some embodiments may have a structure in which a plurality of cell transistors CT21, CT22, CT31, CT32, CT41 and CT42 are connected to one magnetic tunnel junction element MTJ2. For example, the OTP unit cell OTPC may include six cell transistors CT21, CT22, CT31, CT32, CT41 and CT42. The second cell transistors CT21 and CT22, the third cell transistors CT31 and CT32 and the fourth cell transistors CT41 and CT42 may be connected in parallel. The number of cell transistors included in the OTP unit cell OTPC is not limited thereto and may vary.

One end of the second magnetic tunnel junction element MTJ2 is connected to the bit line BL, and the other end of the second magnetic tunnel junction element MTJ2 is connected to one end of the (2-1)th cell transistor CT21 and one end of the (2-2)th cell transistor CT22. The other end of the (2-1)th cell transistor CT21 and the other end of the (2-2)th cell transistor CT22 are connected to the source line SL. A gate electrode of the (2-1)th cell transistor CT21 and a gate electrode of the (2-2)th cell transistor CT22 may be connected to the second word line WL_O_1. The (2-1)th cell transistor CT21 and the (2-2)th cell transistor CT22 may be turned on or off by a signal (or voltage) provided through the second word line WL_O_1.

One end of the third magnetic tunnel junction element MTJ3 is connected to the bit line BL. The other end of the third magnetic tunnel junction element MTJ3 is not connected to one end of the (3-1)th cell transistor CT31 and one end of the (3-2)th cell transistor CT32, and the third magnetic tunnel junction element MTJ3 is electrically separated from the third cell transistors CT31 and CT32. One end of the (3-1)th cell transistor CT31 and one end of the (3-2)th cell transistor CT32 are connected to the other end of the second magnetic tunnel junction element MTJ2. The other end of the (3-1)th cell transistor CT31 and the other end of the (3-2)th cell transistor CT32 are connected to the source line SL. A gate electrode of the (3-1)th cell transistor CT31 and a gate electrode of the (3-2)th cell transistor CT32 may be connected to the third word line WL_O_2. The (3-1)th cell transistor CT31 and the (3-2)th cell transistor CT32 may be turned on or off by a signal (or voltage) provided through the third word line WL_O_2.

One end of the fourth magnetic tunnel junction element MTJ4 is connected to the bit line BL, the other end of the fourth magnetic tunnel junction element MTJ4 is not connected to one end of the (4-1)th cell transistor CT41 and one end of the (4-2)th cell transistor CT42, and the fourth magnetic tunnel junction element MTJ4 is electrically separated from the fourth cell transistors CT41 and CT42. One end of the (4-1)th cell transistor CT41 and one end of the (4-2)th cell transistor CT42 are connected to the other end of the second magnetic tunnel junction element MTJ2. The other end of the (4-1)th cell transistor CT41 and the other end of the (4-2)th cell transistor CT42 are connected to the source line SL. A gate electrode of the (4-1)th cell transistor CT41 and a gate electrode of the (4-2)th cell transistor CT42 may be connected to the fourth word line WL_O_3. The (4-1)th cell transistor CT41 and the (4-2)th cell transistor CT42 may be turned on or off by a signal (or a voltage) provided through the fourth word line WL_O_3.

The third and fourth magnetic tunnel junction elements MTJ3 and MTJ4 may be dummy magnetic tunnel junction elements. The third and fourth magnetic tunnel junction elements MTJ3 and MTJ4 may be unused magnetic tunnel junction elements.

A pair of the second magnetic tunnel junction element MTJ2 and the second cell transistors CT21 and CT22, a pair of the third magnetic tunnel junction element MTJ3 and the third cell transistors CT31 and CT32, and a pair of the fourth magnetic tunnel junction element MTJ4 and the fourth cell transistors CT41 and CT42 of the OTP unit cell OTPC may be respectively disposed in the memory cell array 10 to have the same repetition periodicity as a pair of the first magnetic tunnel junction element MTJ1 and the first cell transistors CT11 and CT12 of the memory unit cell MC.

Each of the first to fourth cell transistors CT11, CT12, CT21, CT22, CT31, CT32, CT41 and CT42 may include at least one of, for example, a diode, a PNP bipolar transistor, an NPN bipolar transistor, an NMOS field effect transistor or a PMOS field effect transistor.

In some embodiments, the memory cell array 10 may include a first region R1 used as MRAM and a second region R2 used as OTP. The plurality of memory unit cells MC are disposed in the first region R1, and the plurality of OTP unit cells OTPC are disposed in the second region R2.

In some embodiments, memory unit cells MC constituting one row and memory unit cells MC constituting another one row may share one source line SL. OTP unit cells OTPC constituting one row and OTP unit cells OTPC constituting another one row may share one source line SL.

In some embodiments, a read path and a write path of the OTP unit cell OTPC may be separated from each other. A portion of the second to fourth cell transistors CT21, CT22, CT31, CT32, CT41 and CT42 of the OTP unit cell OTPC may be used during a read operation of the OTP unit cell OTPC, and the other portion thereof may be used during a write operation of the OTP unit cell OTPC.

For example, the second cell transistors CT21 and CT22 connected to the second word line WL_O_1 may be used during the read operation of the OTP unit cell OTPC, and the third cell transistors CT31 and CT32 connected to the third word line WL_O_2 and the fourth cell transistors CT41 and CT42 connected to the fourth word line WL_O_3 may be used during the write operation of the OTP unit cell OTPC.

For example, the third word line WL_O_2 may be connected to the fourth word line WL_O_3. The third word line WL_O_2 and the fourth word line WL_O_3 may be the same word lines. Gates of the third cell transistors CT31 and CT32 and the fourth cell transistors CT41 and CT42 may be operated by the same word line voltage, and may be operated by word line voltages different from gates of the second cell transistors CT21 and CT22.

Alternatively, the second to fourth word lines WL_O_1, WL_O_2 and WL_O_3 may be different word lines. The gates of the second cell transistors CT21 and CT22, the gates of the third cell transistors CT31 and CT32 and the gates of the fourth cell transistors CT41 and CT42 may be operated by different word line voltages.

In some embodiments, the read path and the write path of the OTP unit cell OTPC may not be separated from each other. The second to fourth cell transistors CT21, CT22, CT31, CT32, CT41 and CT42 of the OTP unit cell OTPC may be used during both the read operation and the write operation of the OTP unit cell OTPC.

The memory cell array 10 may be electrically connected to a peripheral circuit. The peripheral circuit may include, for example, the row decoder 20, the column decoder 30, the write driver 40, the sensing circuit 50, the source line driver 60, the input/output circuit 70, the control logic 80, etc. of FIG. 1. The memory unit cells MC and the OTP unit cells OTPC may be electrically connected to the peripheral circuit. That is, the memory unit cells MC and the OTP unit cells OTPC may share the peripheral circuit.

In some embodiments, the OTP unit cells OTPC may be connected to specific word lines (e.g., the second to fourth word lines WL_O_1, WL_O_2 and WL_O_3).

The first word lines WL and the memory unit cells MC connected to the first word lines WL may be disposed in the first region R1, and OTP unit cells OTPC connected to the second word lines WL_O_1 and the third word lines WL_O_2 may be disposed in the second region R2. Only the memory unit cells MC may be connected to the first word line WL, and only the OTP unit cells OTPC may be connected to the second to fourth word lines WL_O_1, WL_O_2 and WL_O_3. The memory unit cells MC and the OTP unit cells OTPC may be connected to one bit line BL.

The arrangement of the first region R1 and the second region R2 in the memory cell array 10 may vary. For example, the second region R2 may be disposed at an edge portion of the memory cell array 10. The OTP unit cells OTPC may be connected to the second to fourth word lines WL_O_1, WL_O_2 and WL_O_3 disposed at the edge portion of the memory cell array 10.

Since the OTP unit cells OTPC are connected to the specific word lines (e.g., the second to fourth word lines WL_O_1, WL_O_2 and WL_O_3), error correction code ECC may be performed for the OTP unit cell OTPC as well as the memory unit cells MC.

Also, a voltage applied to the second to fourth word lines WL_O_1, WL_O_2 and WL_O_3 may be increased during the write operation of the OTP unit cell OTPC, whereby resistance of the second to fourth cell transistors CT21, CT22, CT31, CT32, CT41 and CT42 of the OTP unit cell OTPC may be reduced without stress of the memory unit cell MC.

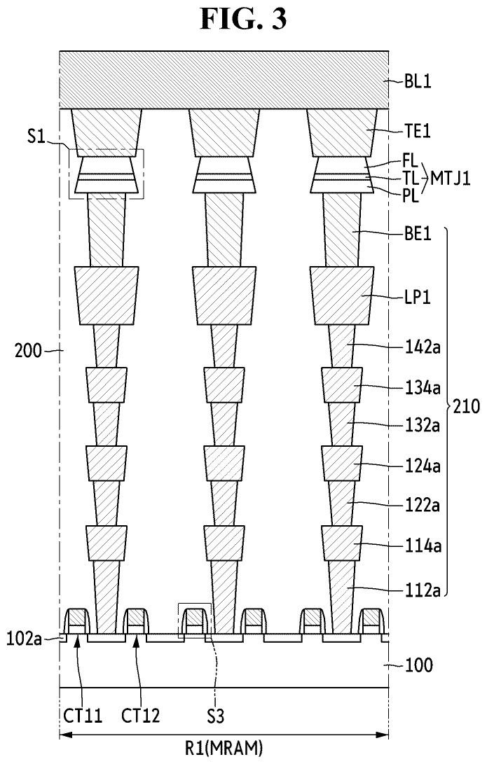

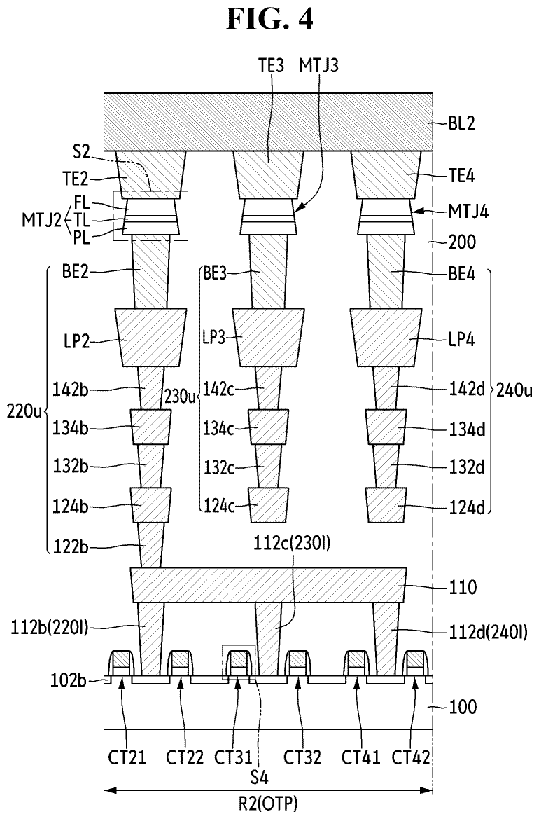

FIGS. 3 and 4 are exemplary cross-sectional views of a magnetic memory device according to some embodiments.

FIG. 3 is an exemplary cross-sectional view of a portion including three memory unit cells MC connected to one bit line in FIG. 2, and FIG. 4 is an exemplary cross-sectional view of a portion including one OTP unit cell OTPC connected to one bit line in FIG. 2. For convenience of description, the source line of FIG. 2 is omitted in FIGS. 3 and 4.

Referring to FIGS. 2 to 4, the magnetic memory device according to some embodiments may include a substrate 100, first to fourth cell transistors CT11, CT12, CT21, CT22, CT31, CT32, CT41, CT42, an insulating film 200, a wiring structure 210, first to third lower wiring structures 2201, 2301, and 2401, first to third upper wiring structures 220u, 230u, and 240u, first to fourth magnetic tunnel junction elements MTJ1, MTJ2, MTJ3 and MTJ4, first to fourth upper electrodes TE1, TE2, TE3 and TE4, and first and second bit lines BL1 and BL2. The bit line BL of FIG. 2 may include a first bit line BL1 connected to the memory unit cell MC and a second bit line BL2 connected to the OTP unit cell OTPC.

Each memory unit cell MC may include first cell transistors CT11 and CT12, a wiring structure 210, a first magnetic tunnel junction element MTJ1 and a first upper electrode TE1.

Each OTP unit cell OTPC may include second to fourth cell transistors CT21, CT22, CT31, CT32, CT41 and CT42, a connection wiring 110, first to third lower wiring structures 2201, 2301, and 2401, first to third upper wiring structures 220u, 230u, and 240u, second to fourth magnetic tunnel junction elements MTJ2, MTJ3 and MTJ4, and second to fourth upper electrodes TE2, TE3 and TE4.

The substrate 100 may be, for example, a silicon substrate, a gallium arsenic substrate, a silicon germanium substrate, a ceramic substrate, a quartz substrate or a display glass substrate, or may be a semiconductor on insulator (SOI) substrate, but is not limited thereto.

The first to fourth cell transistors CT11, CT12, CT21, CT22, CT31, CT32, CT41 and CT42 may be formed on the substrate 100. A first impurity region 102a may be formed on the substrate 100 at both sides of the first cell transistors CT11 and CT12. The first impurity region 102a may be provided as a source region or a drain region of the first cell transistors CT11 and CT12. A second impurity region 102b may be formed on the substrate 100 at both sides of each of the second to fourth cell transistors CT21, CT22, CT31, CT32, CT41 and CT42. The second impurity region 102b may be provided as a source region or a drain region of each of the second to fourth cell transistors CT21, CT22, CT31, CT32, CT41 and CT42. The first impurity region 102a and the second impurity region 102b may include N-type or P-type impurities, respectively.

In some embodiments, the first to fourth cell transistors CT11, CT12, CT21, CT22, CT31, CT32, CT41 and CT42 may have the same threshold voltage.

The insulating film 200 may be formed on the substrate 100. The insulating film 200 may cover the first cell transistors CT11 and CT12. The connection wiring 110, the first to third lower wiring structures 2201, 2301, and 2401, the first to third upper wiring structures 220u, 230u, and 240u, the first to fourth magnetic tunnel junction elements MTJ1, MTJ2, MTJ3 and MTJ4 and the first to fourth upper electrodes TE1, TE2, TE3 and TE4 may be formed in the insulating film 200. The insulating film 200 may include, for example, silicon oxide or silicon oxynitride. The insulating film 200 may have a multi-layered structure.

The first to fourth magnetic tunnel junction elements MTJ1, MTJ2, MTJ3 and MTJ4 may be formed on the substrate 100. The first to fourth magnetic tunnel junction elements MTJ1, MTJ2, MTJ3 and MTJ4 may be formed at the same height from the substrate 100.

The wiring structure 210, the first to third lower wiring structures 2201, 2301, and 2401 and the first to third upper wiring structures 220u, 230u, and 240u may be formed on the substrate 100.

The wiring structure 210 may connect the substrate 100 with the first magnetic tunnel junction element MTJ1. The wiring structure 210 may include a (1-1)th via 112a, a (1-1)th wiring 114a, a (2-1)th via 122a, a (2-1)th wiring 124a, a (3-1)th via 132a, a (3-1)th wiring 134a, a (4-1)th via 142a, a first landing pad LP1 and a first lower electrode BE1, which are sequentially stacked on the substrate 100. The (1-1)th via 112a may be connected to the first impurity region 102a. The (2-1)th via 122a may connect the (1-1)th wiring 114a with the (2-1)th wiring 124a. The (3-1)th via 132a may connect the (2-1)th wiring 124a with the (3-1)th wiring 134a. The (4-1)th via 142a may connect the (3-1)th wiring 134a with the first landing pad LP1. The first lower electrode BE1 may connect the first landing pad LP1 with the first magnetic tunnel junction element MTJ1.

The first upper electrode TE1 may be formed on the first magnetic tunnel junction element MTJ1. The first upper electrode TE1 may be connected to the first magnetic tunnel junction element MTJ1. The first bit line BL1 may be formed on the first upper electrode TE1. The first bit line BL1 may be connected to the first upper electrode TE1. The first magnetic tunnel junction element MTJ1 may be electrically connected to the first cell transistors CT11 and CT12 through the wiring structure 210, and may be electrically connected to the first bit line BL1 through the first upper electrode TE1.

The connection wiring 110 may be disposed on the substrate 100. In some embodiments, the connection wiring 110 may be disposed at the lowest metal level among the wirings. The connection wiring 110 may be the wiring closest to the substrate 100. The second to fourth cell transistors CT21, CT22, CT31, CT32, CT41 and CT42 may be electrically connected through the connection wiring 110 having a metal level closest to the substrate 100. The connection wiring 110 may be formed at the same height from the (1-1)th wiring 114a and the substrate 100. That is, the wirings disposed at the same metal level as that of the (1-1)th wiring 114a may be directly connected to each other below the second to fourth magnetic tunnel junction elements MTJ2, MTJ3 and MTJ4.

The third and fourth magnetic tunnel junction elements MTJ3 and MTJ4 may be separated from the connection wiring 110 at a metal level higher than that of the connection wiring 110. In some embodiments, the via having the same metal level as that of the via that is in direct contact with the connection wiring 110 may be omitted between the third and fourth magnetic tunnel junction elements MTJ3 and MTJ4 and the connection wiring 110. For example, the via having the same metal level as that of the (2-2)th via 122b may be omitted between the third magnetic tunnel junction element MTJ3 and the connection wiring 110 and between the fourth magnetic tunnel junction elements MTJ4 and the connection wiring 110.

The metal level at which the connection wiring 110 is disposed and the metal level at which the via (or wiring) omitted between the third magnetic tunnel junction element MTJ3 and the connection wiring 110 and between the fourth magnetic tunnel junction element MTJ4 and the connection wiring 110 is disposed may vary depending on the design of the magnetic memory device.

The first to third lower wiring structures 2201, 2301 and 2401 may be spaced apart from one another in a horizontal direction. Each of the first to third lower wiring structures 2201, 2301 and 2401 may connect the substrate 100 with the connection wiring 110.

The first lower wiring structure 2201 may include a (1-2)th via 112b. The second lower wiring structure 2301 may include a (1-3)th via 112c. The third lower wiring structure 2401 may include a (1-4)th via 112d. Each of the (1-2)th to (1-4)th vias 112b, 112c and 112d may connect the second impurity region 102b with the connection wiring 110. The (1-1)th to (1-4)th vias 112a, 112b, 112c and 112d may be formed at the same height from the substrate 100.

The first to third upper wiring structures 220u, 230u and 240u may be formed on the connection wiring 110. The first to third upper wiring structures 220u, 230u and 240u may be spaced apart from one another in the horizontal direction. Each of the first to third upper wiring structures 220u, 230u and 240u may be connected to each of the second to fourth magnetic tunnel junction elements MTJ2, MTJ3 and MTJ4.

The first upper wiring structure 220u may be disposed between the connection wiring 110 and the second magnetic tunnel junction element MTJ2. The first upper wiring structure 220u may connect the connection wiring 110 with the second magnetic tunnel junction element MTJ2. The first upper wiring structure 220u may include a (2-2)th via 122b, a (2-2)th wiring 124b, a (3-2)th via 132b, a (3-2)th wiring 134b, a (4-2)th via 142b, a second landing pad LP2 and a second lower electrode BE2. The (2-2)th via 122b may connect the connection wiring 110 with the (2-2)th wiring 124b. The (3-2)th via 132b may connect the (2-2)th wiring 124b with the (3-2)th wiring 134b. The (4-2)th via 142b may connect the (3-2)th wiring 134b with the second landing pad LP2. The second lower electrode BE2 may connect the second landing pad LP2 with the second magnetic tunnel junction element MTJ2.

The second upper wiring structure 230u may be disposed between the connection wiring 110 and the third magnetic tunnel junction element MTJ3. The second upper wiring structure 230u may be spaced apart from the connection wiring 110, and may be connect to the third magnetic tunnel junction element MTJ3. The second upper wiring structure 230u may include a (2-3)th wiring 124c, a (3-3)th via 132c, a (3-3)th wiring 134c, a (4-3)th via 142c, a third landing pad LP3 and a third lower electrode BE3, which are sequentially stacked on the connection wiring 110. The (2-3)th wiring 124c may be spaced apart from the connection wiring 110. The (2-3)th wiring 124c may not be in direct contact with the connection wiring 110. The (3-3)th via 132c may connect the (2-3)th wiring 124c with the (3-3)th wiring 134c. The (4-3)th via 142c may connect the (3-3)th wiring 134c with the third landing pad LP3. The third lower electrode BE3 may connect the third landing pad LP3 with the third magnetic tunnel junction element MTJ3.

The third upper wiring structure 240u may be disposed between the connection wiring 110 and the fourth magnetic tunnel junction element MTJ4. The third upper wiring structure 240u may be spaced apart from the connection wiring 110, and may be connected to the fourth magnetic tunnel junction element MTJ4. The third upper wiring structure 240u may include a (2-4)th wiring 124d, a (3-4)th via 132d, a (3-4)th wiring 134d, a (4-4)th via 142d, a fourth landing pad LP4 and a fourth lower electrode BE4, which are sequentially stacked on the connection wiring 110. The (2-4)th wiring 124d may be spaced apart from the connection wiring 110. The (2-4)th wiring 124d may not be in direct contact with the connection wiring 110. The (3-4)th via 132d may connect the (2-4)th wiring 124d with the (3-4)th wiring 134d. The (4-4)th via 142d may connect the (3-4)th wiring 134d with the fourth landing pad LP4. The fourth lower electrode BE4 may connect the fourth landing pad LP4 with the fourth magnetic tunnel junction element MTJ4.

The (2-1)th via 122a and the (2-2)th via 122b may be formed at the same height from the substrate 100. The (2-1)th to (2-4)th wirings 124a, 124b, 124c and 124d may be formed at the same height from the substrate 100. The (3-1)th to (3-4)th vias 132a, 132b, 132c and 132d may be formed at the same height from the substrate 100. The (3-1)th to (3-4)th wirings 134a, 134b, 134c and 134d may be formed at the same height from the substrate 100. The (4-1)th to (4-4)th vias 142a, 142b, 142c and 142d may be formed at the same height from the substrate 100. The first to fourth landing pads LP1, LP2, LP3 and LP4 may be formed at the same height from the substrate 100. The first to fourth lower electrodes BE1, BE2, BE3 and BE4 may be formed at the same height from the substrate 100.

The second to fourth upper electrodes TE2, TE3 and TE4 may be formed on the second to fourth magnetic tunnel junction elements MTJ2, MTJ3 and MTJ4, respectively. The second to fourth upper electrodes TE2, TE3 and TE4 may be connected to the second to fourth magnetic tunnel junction elements MTJ2, MTJ3 and MTJ4, respectively. The first to fourth upper electrodes TE1, TE2, TE3 and TE4 may be formed at the same height from the substrate 100.

The second bit line BL2 may be formed on the second to fourth upper electrodes TE2, TE3 and TE4. The second bit line BL2 may be connected to the second to fourth upper electrodes TE2, TE3 and TE4. The first and second bit lines BL1 and BL2 may be formed at the same height from the substrate 100.

The second magnetic tunnel junction element MTJ2 may be electrically connected to the second to fourth cell transistors CT21, CT22, CT31, CT32, CT41 and CT42 through the first upper wiring structure 220u, the connection wiring 110 and the first to third lower wiring structures 2201, 2301, and 2401, and may be electrically connected to the second bit line BL2 through the second upper electrode TE2.

Each of the (1-1)th to (1-4)th vias 112a, 112b, 112c and 112d, the (2-1)th via 122a, the (2-2)th via 122b, the (2-1)th to (2-4)th wirings 124a, 124b, 124c and 124d, the (3-1)th to (3-4)th vias 132a, 132b, 132c and 132d, the (3-1)th to (3-4)th wirings 134a, 134b, 134c and 134d, and the (4-1)th to (4-4)th vias 142a, 142b, 142c and 142d may include metal (e.g., copper). Each of the first to fourth landing pads LP1, LP2, LP3 and LP4 may include at least one of a doped semiconductor material (e.g., doped silicon), metal (e.g., tungsten, titanium and/or tantalum), a metal-semiconductor compound (e.g., metal silicide) or a conductive metal nitride (e.g., titanium nitride, tantalum nitride and/or tungsten nitride). Each of the first to fourth lower electrodes BE1, BE2, BE3 and BE4 may include, for example, a conductive metal nitride (e.g., titanium nitride or tantalum nitride). Each of the first to fourth upper electrodes TE1, TE2, TE3 and TE4 may include at least one of metal (e.g., Ta, W, Ru, Ir, etc.) or a conductive metal nitride (e.g., TiN).

In some embodiments, the second to fourth magnetic tunnel junction elements MTJ2, MTJ3 and MTJ4 may have the same size as that of the first magnetic tunnel junction element MTJ1.

Each of the first to fourth magnetic tunnel junction elements MTJ1, MTJ2, MTJ3 and MTJ4 may include a first magnetic pattern PL, a tunnel barrier pattern TL and a second magnetic pattern FL. The tunnel barrier pattern TL may be interposed between the first magnetic pattern PL and the second magnetic pattern FL.

One of the first magnetic pattern PL and the second magnetic pattern FL may be a reference layer having a fixed magnetization direction regardless of an external magnetic field, and the other one of the first magnetic pattern PL and the second magnetic pattern FL may be a free layer that is variable between two stable magnetization directions. For example, the first magnetic pattern PL may be a reference layer having a fixed magnetization direction, and the second magnetic pattern FL may be a free layer having a variable magnetization direction. For another example, the first magnetic pattern PL may be a free layer, and the second magnetic pattern FL may be a reference layer.

In some embodiments, each of the first magnetic pattern PL and the second magnetic pattern FL may have a perpendicular magnetic anisotropy (PMA). Each of the first magnetic pattern PL and the second magnetic pattern FL may have a magnetization easy axis in a vertical direction (a direction perpendicular to an upper surface of the substrate 100).

Each of the first magnetic pattern PL and the second magnetic pattern FL may include at least one of a vertical magnetic material (e.g., CoFeTb, CoFeGd, CoFeDy), a vertical magnetic material having an Llo structure, a CoPt having a hexagonal close packed lattice structure or a vertical magnetic structure. The vertical magnetic material having the Llo structure may include, for example, FePt of the Llo structure, FePd of the Llo structure, CoPd of the Llo structure or CoPt of the Llo structure. The vertical magnetic structure may include magnetic layers and non-magnetic layers, which are alternately and repeatedly stacked. For example, the vertical magnetic structure may include (Co/Pt)ₙ, (CoFe/Pt)ₙ, (CoFe/Pd)ₙ, (Co/Pd)ₙ, (Co/Ni)ₙ, (CoNi/Pt)ₙ, (CoCr/Pt)ₙ or (CoCr/Pd)ₙ (where n is the number of stacked times).

In some embodiments, each of the first magnetic pattern PL and the second magnetic pattern FL may have an in-plane magnetic anisotropy (IMA). Each of the first magnetic pattern PL and the second magnetic pattern FL may have a magnetization easy axis in a horizontal direction (a direction parallel with the upper surface of the substrate 100).

Each of the first magnetic pattern PL and the second magnetic pattern FL having the in-plane in-plane magnetic anisotropy (IMA) may include a ferromagnetic material. In some embodiments, the magnetic pattern, which forms the reference layer, of the first magnetic pattern PL and the second magnetic pattern FL may further include an anti-ferromagnetic material for fixing the magnetization direction of the ferromagnetic material. For example, the ferromagnetic material of the reference layer may include at least one of CoFeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO or Y₃Fe₅O₁₂. For example, the anti-ferromagnetic material of the reference layer may include at least one of PtMn, IrMn, MnO, MnS, MnTe, MnF₂, FeCₗ₂, FeO, CoCₗ₂, CoO, NiCl₂, NiO or Cr, or at least one selected from a precious metal. The precious metal may include ruthenium (Ru), rhodium (Rh), palladium (Pd), osmium (Os), iridium (Ir), platinum (Pt), gold (Au) or silver (Ag). For example, the ferromagnetic material of the free layer may include at least one of FeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO or Y₃Fe₅O₁₂. The magnetic pattern which is the free layer may be composed of a plurality of layers.

The tunnel barrier pattern TL may include, for example, at least one selected from an oxide of magnesium (Mg), titanium (Ti), aluminum (Al), magnesium-zinc (MgZn) and magnesium-boron (MgB), or a nitride of titanium (Ti) and vanadium (V).

The first magnetic tunnel junction element MTJ1 may store data in each memory unit cell MC by using a difference in electrical resistance according to the magnetization direction of the first magnetic pattern PL and the magnetization direction of the second magnetic pattern FL.

For example, when the magnetization direction of the first magnetic pattern PL is parallel with the magnetization direction of the second magnetic pattern FL, the first magnetic tunnel junction element MTJ1 may have a low resistance value, and may store data 0. On the contrary, when the magnetization direction of the first magnetic pattern PL is anti-parallel with the magnetization direction of the second magnetic pattern FL, the first magnetic tunnel junction element MTJ1 may have a high resistance value, and may store data 1. For another example, when the magnetization direction of the first magnetic pattern PL is parallel with the magnetization direction of the second magnetic pattern FL, the first magnetic tunnel junction element MTJ1 may store data 1, and when the magnetization direction of the first magnetic pattern PL is anti-parallel with the magnetization direction of the second magnetic pattern FL, the first magnetic tunnel junction element MTJ1 may store data 0.

The second magnetic tunnel junction element MTJ2 may insulate and break the tunnel barrier pattern TL between the first magnetic pattern PL and the second magnetic pattern FL by applying a breakdown voltage to both ends of the first magnetic pattern PL and the second magnetic pattern FL through programming operation of one time, thereby having an irreversible resistance state. The insulated and broken second magnetic tunnel junction element MTJ2 may be in a shorted state. The insulated and broken second magnetic tunnel junction element MTJ2 may have a low resistance value, and may store data 0. The second magnetic tunnel junction element MTJ2 that is neither insulated nor broken may have a high resistance value and store data 1.

When FIGS. 3 and 4 are cross-sectional views of three memory unit cell (MC) portions and one OTP unit cell (OTPC) portion, which are connected to the same bit line of FIG. 2, the first bit line BL1 of FIG. 3 may be the same bit line as the second bit line BL2 of FIG. 4. When FIGS. 3 and 4 are cross-sectional views of three memory unit cell (MC) portions and one OTP unit cell (OTPC) portion, which are connected to different bit lines of FIG. 2, the first bit line BL1 of FIG. 3 may be a different bit line from the second bit line BL2 of FIG. 4.

The memory cell array 10 of the magnetic memory device according to some embodiments includes memory unit cells MC used as MRAM and OTP unit cells OTPC used as OTP. That is, since the memory unit cells MC and the OTP unit cells OTPC are implemented in one memory cell array 10 without a separate OTP memory, a highly integrated magnetic memory device may be provided.

During the write operation of the OTP unit cell OTPC, the breakdown voltage is applied to the second magnetic tunnel junction MTJ2 to insulate and break the tunnel barrier pattern TL of the second magnetic tunnel junction element MTJ2. The breakdown voltage has a value higher than the write voltage applied to the first magnetic tunnel junction MTJ1 during the write operation of the memory unit cell MC. As a result, stress may be applied to the memory unit cell MC.

On the other hand, in the magnetic memory device according to some embodiments, since the OTP unit cell OTPC includes second to fourth cell transistors CT21, CT22, CT31, CT32, CT41 and CT42 connected in parallel, a larger voltage may be applied to both ends of the second magnetic tunnel junction MTJ2. Therefore, even though the write voltage applied to the OTP unit cell OTPC is not significantly increased, insulation breakdown of the tunnel barrier pattern TL of the second magnetic tunnel junction MTJ2 may occur more easily. Also, the stress of the memory unit cell MC due to the write voltage applied to the OTP unit cell OTPC may be improved and/or reduced.

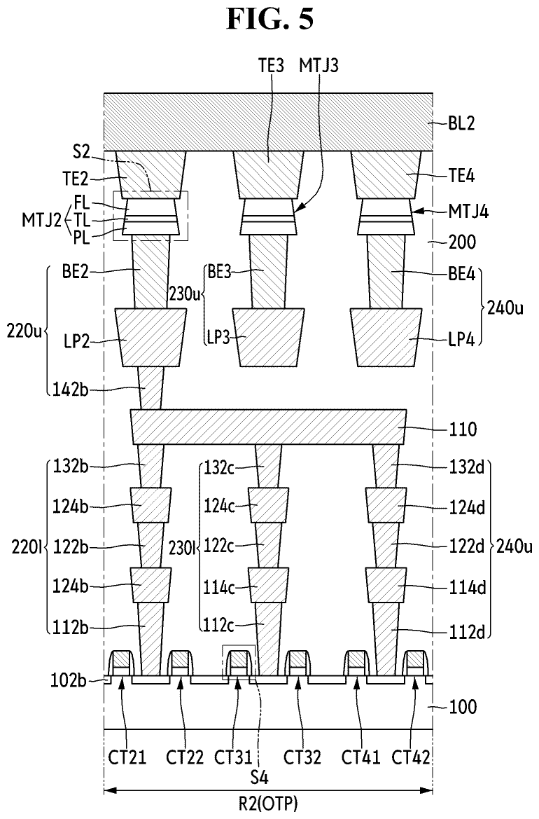

FIG. 5 is an exemplary cross-sectional view of a magnetic memory device according to some embodiments. FIG. 5 is an exemplary cross-sectional view of a portion including one OTP unit cell OTPC connected to one bit line in FIG. 2. For convenience of description, the source line of FIG. 2 is omitted in FIG. 5. For convenience of description, portions repeated with those described with reference to FIGS. 1 to 4 will be briefly described or omitted.

Referring to FIG. 5, in some embodiments, the connection wiring 110 may be formed at the same height from the (3-1)th wiring 134a of FIG. 3 and the substrate 100. That is, wirings disposed at the same metal level as the (3-1)th wiring 134a of FIG. 3 may be directly connected to each other below the second to fourth magnetic tunnel junction elements MTJ2, MTJ3 and MTJ4.

Vias of the same metal level as the (4-2)th via 142b may be omitted between the third magnetic tunnel junction element MTJ3 and the connection wiring 110 and between the fourth magnetic tunnel junction elements MTJ4 and the connection wiring 110.

The first lower wiring structure 2201 may include a (1-2)th via 112b, a (1-2)th wiring 114b, a (2-2)th via 122b, a (2-2)th wiring 124b and a (3-2)th via 132b, which are sequentially stacked on the substrate 100. The second lower wiring structure 2301 may include a (1-3)th via 112c, a (1-3)th wiring 114c, a (2-3)th via 122c, a (2-3)th wiring 124c and a (3-3)th via 132c, which are sequentially stacked on the substrate 100. The third lower wiring structure 2401 may include a (1-4)th via 112d, a (1-4)th wiring 114d, a (2-4)th via 122d, a (2-4)th wiring 124d and a (3-4)th via 132d, which are sequentially stacked on the substrate 100. Each of the (2-2)th to (2-4)th vias 122b, 122c and 122d may connect each of the (1-2)th to (1-4)th wirings 114b, 114c and 114d to the (2-2)th to (2-4)th wirings 124b, 124c and 124d. Each of the (3-2)th to (3-4)th vias 132b, 132c and 132d may connect each of the (2-2)th to (2-4)th wirings 124b, 124c and 124d to the connection wiring 110.

The first upper wiring structure 220u may include a (4-2)th via 142b, a second landing pad LP2 and a second lower electrode BE2, which are sequentially stacked on the connection wiring 110. The (4-2)th via 142b may connect the connection wiring 110 with the second landing pad LP2. The second upper wiring structure 230u may include a third landing pad LP3 and a third lower electrode BE3, which are sequentially stacked on the connection wiring 110. The third landing pad LP3 may be spaced apart from the connection wiring 110. The third landing pad LP3 may not be in direct contact with the connection wiring 110. The third upper wiring structure 240u may include a fourth landing pad LP4 and a fourth lower electrode BE4, which are sequentially stacked on the connection wiring 110. The fourth landing pad LP4 may be spaced apart from the connection wiring 110. The fourth landing pad LP4 may not be in direct contact with the connection wiring 110.

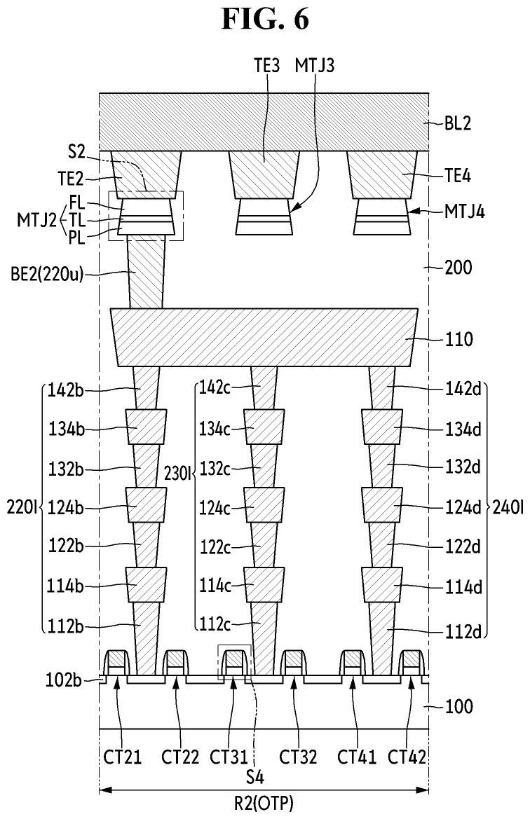

FIG. 6 is an exemplary cross-sectional view of a magnetic memory device according to some embodiments. FIG. 6 is an exemplary cross-sectional view of a portion including one OTP unit cell OTPC connected to one bit line in FIG. 2. For convenience of description, the source line of FIG. 2 is omitted in FIG. 6. For convenience of description, portions repeated with those described with reference to FIGS. 1 to 5 will be briefly described or omitted.

Referring to FIG. 6, in some embodiments, the connection wiring 110 may be formed at the same height from the first landing pad (LP1 of FIG. 3) and the substrate 100. That is, wirings disposed at the same metal level as that of the first landing pad (LP1 of FIG. 3) may be directly connected to each other below the second to fourth magnetic tunnel junction elements MTJ2, MTJ3 and MTJ4.

A via having the same metal level as that of the second lower electrode BE2 may be omitted between the third magnetic tunnel junction element MTJ3 and the connection wiring 110 and between the fourth magnetic tunnel junction elements MTJ4 and the connection wiring 110.

The first lower wiring structure 2201 may include a (1-2)th via 112b, a (1-2)th wiring 114b, a (2-2)th via 122b, a (2-2)th wiring 124b, a (3-2)th via 132b, a (3-2)th wiring 134b and a (4-2)th via 142b, which are sequentially stacked on the substrate 100. The second lower wiring structure 2301 may include a (1-3)th via 112c, a (1-3)th wiring 114c, a (2-3)th via 122c, a (2-3)th wiring 124c, a (3-3)th via 132c, a (3-3)th wiring 134c, and a (4-3)th via 142c, which are sequentially stacked on the substrate 100. The third lower wiring structure 2401 may include a (1-4)th via 112d, a (1-4)th wiring 114d, a (2-4)th via 122d, a (2-4)th wiring 124d, a (3-4)th via 132d, a (3-4)th wiring 134d and a (4-4)th via 142d, which are sequentially stacked on the substrate 100. Each of the (4-2)th to (4-4)th vias 142b, 142c and 142d may connect the (3-2)th to (3-4)th wirings 134b, 134c and 134d to the connection wiring 110.

The first upper wiring structure 220u may include a second lower electrode BE2. The second lower electrode BE2 may connect the connection wiring 110 to the second magnetic tunnel junction element MTJ2. The second upper wiring structure (230u of FIGS. 3 and 4) and the third upper wiring structure (240u of FIGS. 3 and 4) may be omitted. The third magnetic tunnel junction element MTJ3 and the fourth magnetic tunnel junction element MTJ4 may be spaced apart from the connection wiring 110. The third magnetic tunnel junction element MTJ3 and the fourth magnetic tunnel junction element MTJ4 may not be in direct contact with the connection wiring 110.

Each OTP unit cell OTPC may include second to fourth cell transistors CT21, CT22, CT31, CT32, CT41 and CT42, a connection wiring 110, first to third lower wiring structures 2201, 2301 and 2401, first upper wiring structures 220u, second to fourth magnetic tunnel junction elements MTJ2, MTJ3 and MTJ4 and second to fourth upper electrodes TE2, TE3 and TE4.

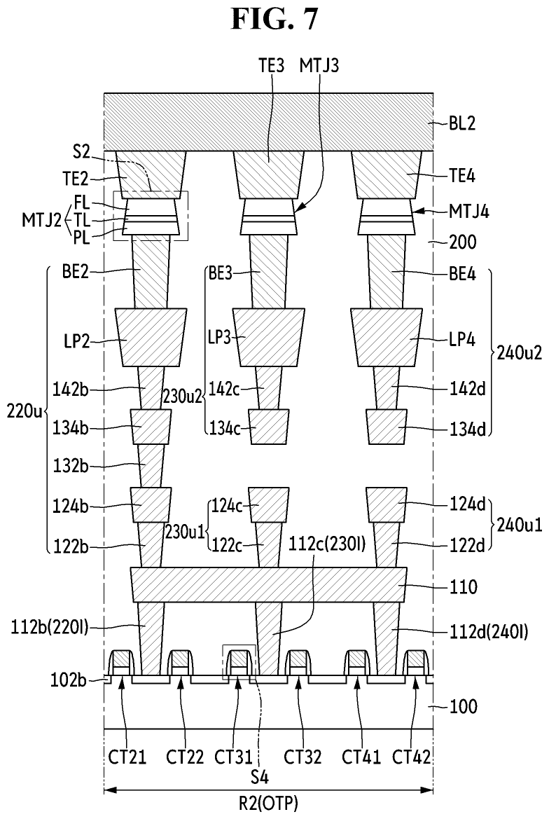

FIG. 7 is an exemplary cross-sectional view of a magnetic memory device according to some embodiments. FIG. 7 is an exemplary cross-sectional view of a portion including one OTP unit cell OTPC connected to one bit line in FIG. 2. For convenience of description, the source line of FIG. 2 is omitted in FIG. 7. For convenience of description, portions repeated with those described with reference to FIGS. 1 to 6 will be briefly described or omitted.

Referring to FIG. 7, in some embodiments, a via having the same metal level as that of the via that is not in direct contact with the connection wiring 110 may be omitted between the third and fourth magnetic tunnel junction elements MTJ3 and MTJ4 and the connection wiring 110. For example, a via having the same metal level as that of the (3-2)th via 132b may be omitted between the third magnetic tunnel junction element MTJ3 and the connection wiring 110 and between the fourth magnetic tunnel junction elements MTJ4 and the connection wiring 110.

A first sub-wiring structure 230u1 and a second sub-wiring structure 230u2 may be disposed between the connection wiring 110 and the third magnetic tunnel junction element MTJ3. The first sub-wiring structure 230u1 may be connected to the connection wiring 110. The second sub-wiring structure 230u2 may be connected to the third magnetic tunnel junction element MTJ3. The first sub-wiring structure 230u1 and the second sub-wiring structure 230u2 may be spaced apart from each other in the vertical direction. The first sub-wiring structure 230u1 and the second sub-wiring structure 230u2 may not be in direct contact with each other.

The first sub-wiring structure 230u1 may include a (2-3)th via 122c and a (2-3)th wiring 124c, which are sequentially stacked on the connection wiring 110. The second sub-wiring structure 230u2 may include a third lower electrode BE3, a third landing pad LP3, a (4-3)th via 142c and a (3-3)th wiring 134c, which are sequentially stacked on a lower portion of the third magnetic tunnel junction element MTJ3. The (2-3)th wiring 124c and the (3-3)th wiring 134c may be spaced apart from each other. The (2-3)th wiring 124c and the (3-3)th wiring 134c may not be in direct contact with each other.

A third sub-wiring structure 240u1 and a fourth sub-wiring structure 240u2 may be disposed between the connection wiring 110 and the fourth magnetic tunnel junction element MTJ4. The third sub-wiring structure 240u1 may be connected to the connection wiring 110. The fourth sub-wiring structure 240u2 may be connected to the fourth magnetic tunnel junction element MTJ4. The third sub-wiring structure 240u1 and the fourth sub-wiring structure 240u2 may be spaced apart from each other in the vertical direction. The third sub-wiring structure 240u1 and the fourth sub-wiring structure 240u2 may not be in direct contact with each other.

The third sub-wiring structure 240u1 may include a (2-4)th via 122d and a (2-4)th wiring 124d, which are sequentially stacked on the connection wiring 110. The fourth sub-wiring structure 240u2 may include a fourth lower electrode BE4, a fourth landing pad LP4, a (4-4)th via 142d and a (3-4)th wiring 134d, which are sequentially stacked on a lower portion of the fourth magnetic tunnel junction element MTJ4. The (2-4)th wiring 124d and the (3-4)th wiring 134d may be spaced apart from each other. The (2-4)th wiring 124d and the (3-4)th wiring 134d may not be in direct contact with each other.

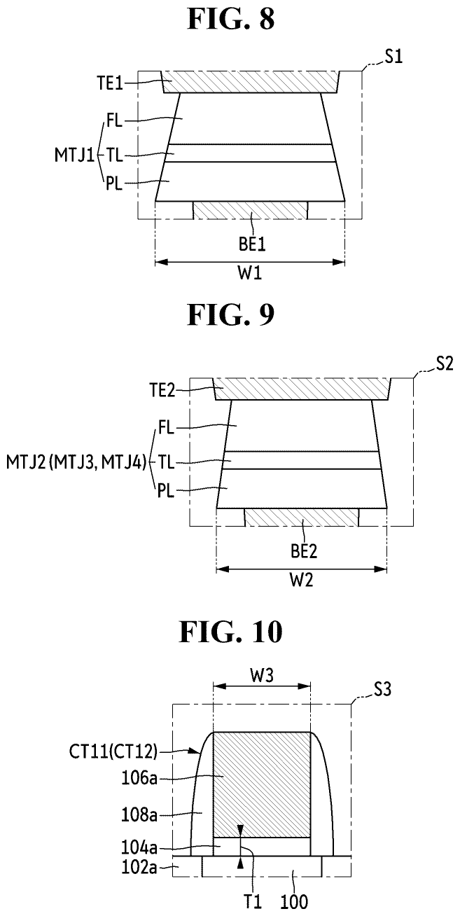

FIG. 8 is an enlarged view of a region S1 of FIG. 3. FIG. 9 is an enlarged view of a region S2 of FIGS. 4 to 7.

Referring to FIGS. 3 to 9, in some embodiments, the resistance values of the magnetic tunnel junction elements MTJ2, MTJ3 and MTJ4 included in the OTP unit cell OTPC may be greater than the resistance values of the magnetic tunnel junction elements MTJ1 included in the memory unit cell MC.

For example, sizes of the magnetic tunnel junction elements MTJ2, MTJ3 and MTJ4 included in the OTP unit cell OTPC may be smaller than a size of the magnetic tunnel junction elements MTJ1 included in the memory unit cell MC. Therefore, the tunnel barrier pattern TL of the second magnetic tunnel junction element MTJ2 may be broken with a smaller current. In addition, since the resistance value of the second magnetic tunnel junction element MTJ2 that is insulated and broken becomes smaller, a lead margin of the second magnetic tunnel junction element MTJ2 may be increased.

For example, a maximum width W2 of the magnetic tunnel junction elements MTJ2, MTJ3 and MTJ4 included in the OTP unit cell OTPC may be smaller than a maximum width W1 of the magnetic tunnel junction element MTJ1 included in the memory unit cell MC. Heights of the magnetic tunnel junction elements MTJ2, MTJ3 and MTJ4 included in the OTP unit cell OTPC may be smaller than a height of the magnetic tunnel junction element MTJ1 included in the memory unit cell MC. In this case, the width is defined based on the horizontal direction (the direction parallel with the upper surface of the substrate), and the height is defined based on the vertical direction (the direction perpendicular to the upper surface of the substrate).

The third and fourth magnetic tunnel junction elements MTJ3 and MTJ4 may have the same size as that of the second magnetic tunnel junction element MTJ2. The maximum width of the third and fourth magnetic tunnel junction elements MTJ3 and MTJ4 may be the same as the maximum width of the second magnetic tunnel junction element MTJ2. The maximum width W2 of the second magnetic tunnel junction element MTJ2 may be smaller than the maximum width W1 of the first magnetic tunnel junction element MTJ1. The height of the third and fourth magnetic tunnel junction elements MTJ3 and MTJ4 may be the same as the height of the second magnetic tunnel junction element MTJ2. The height of the second magnetic tunnel junction element MTJ2 may be smaller than the height of the first magnetic tunnel junction element MTJ1.

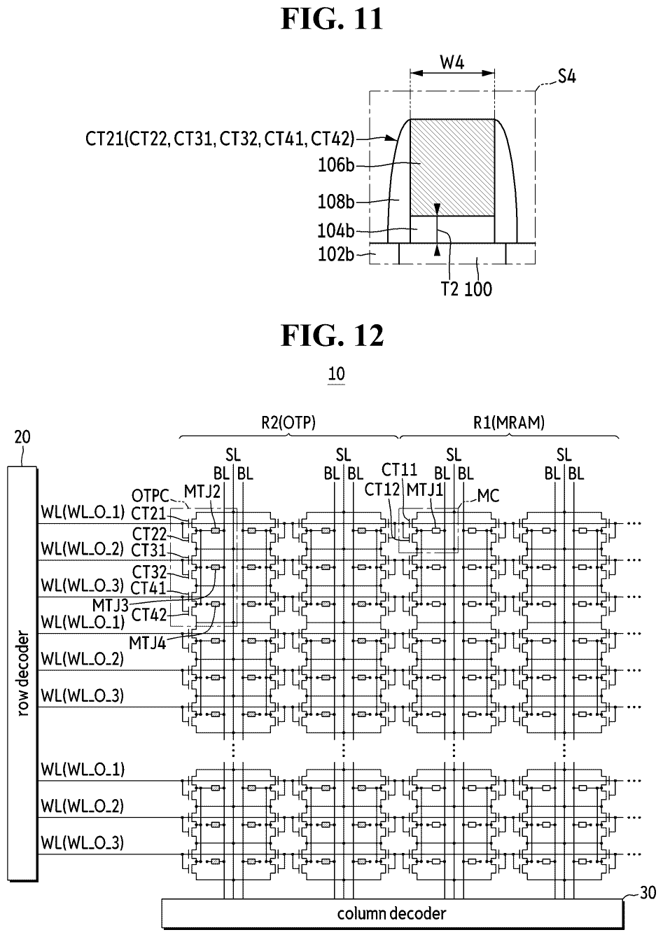

FIG. 10 is an enlarged view of a region S3 of FIG. 3. FIG. 11 is an enlarged view of a region S4 of FIGS. 4 to 7.

Referring to FIGS. 3 to 7 and FIGS. 10 and 11, in some embodiments, threshold voltages of the cell transistors CT21, CT22, CT31, CT32, CT41 and CT42 included in the OTP unit cell OTPC may be smaller than threshold voltages of the cell transistors CT11 and CT12 included in the memory unit cell MC. The cell transistors CT21, CT22, CT31, CT32, CT41 and CT42 included in the OTP unit cell OTPC may be high voltage transistors that operate under a high voltage, and the cell transistors CT11 and CT12 included in the memory unit cell MC may be low voltage transistors that operate under a low voltage. Therefore, a stable high voltage may be applied to the OTP unit cell OTPC.

The (1-1)th cell transistor CT11 may include a first gate dielectric film 104a, a first gate electrode 106a and a first gate spacer 108a. The (1-2)th cell transistor CT12 may have the same structure as that of the (1-1)th cell transistor CT11. The (2-1)th cell transistor CT21 may include a second gate dielectric film 104b, a second gate electrode 106b and a second gate spacer 108b. The (2-2)th, (3-1)th, (3-2)th, (4-1)th and (4-2)th cell transistors CT22, CT31, CT32, CT41 and CT42 may have the same structure as that of the (2-1)th cell transistor CT21.

Each of the first and second gate dielectric films 104a and 104b may include, for example, at least one of silicon oxide or a high dielectric material. Each of the first and second gate electrodes 106a and 106b may include at least one of a semiconductor material doped with a dopant, metal, a conductive metal nitride or a metal-semiconductor compound. Each of the first and second gate spacers 108a and 108b may include at least one of, for example, silicon oxide, silicon nitride or silicon oxynitride.

In some embodiments, a width W3 of the first gate electrode 106a may be greater than a width W4 of the second gate electrode 106b.

In some embodiments, a thickness T1 of the first gate dielectric film 104a may be smaller than a thickness T2 of the second gate dielectric film 104b.

FIG. 12 is an exemplary circuit diagram illustrating a magnetic memory device according to some embodiments. For convenience of description, portions repeated with those described with reference to FIGS. 1 to 11 will be briefly described or omitted.

Referring to FIG. 12, in some embodiments, the OTP unit cells OTPC may be connected to a specific bit line BL. For example, the OTP unit cells OTPC may be connected to a bit line BL disposed at an edge portion of the memory cell array 10.

Only memory unit cells MC may be connected to one bit line BL, or only OTP unit cells OTPC may be connected thereto. The memory unit cells MC and the OTP unit cells OTPC may be connected to one word line WL.

In some embodiments, since the OTP unit cells OTPC are connected to the specific bit line BL, the voltage applied to the bit line BL or the source line SL, which is connected to the OTP unit cell OTPC, may be increased during the write operation of the OTP unit cell OTPC, whereby a magnitude of the voltage applied to both ends of the second magnetic tunnel junction element MTJ2 may be increased without increase in stress of the memory unit cell MC.

FIG. 3 may be an exemplary cross-sectional view of a portion including three memory unit cells MC connected to one bit line in FIG. 12, and FIGS. 4 to 7 may be exemplary cross-sectional views of a portion including one OTP unit cell OTPC connected to one bit line in FIG. 12.

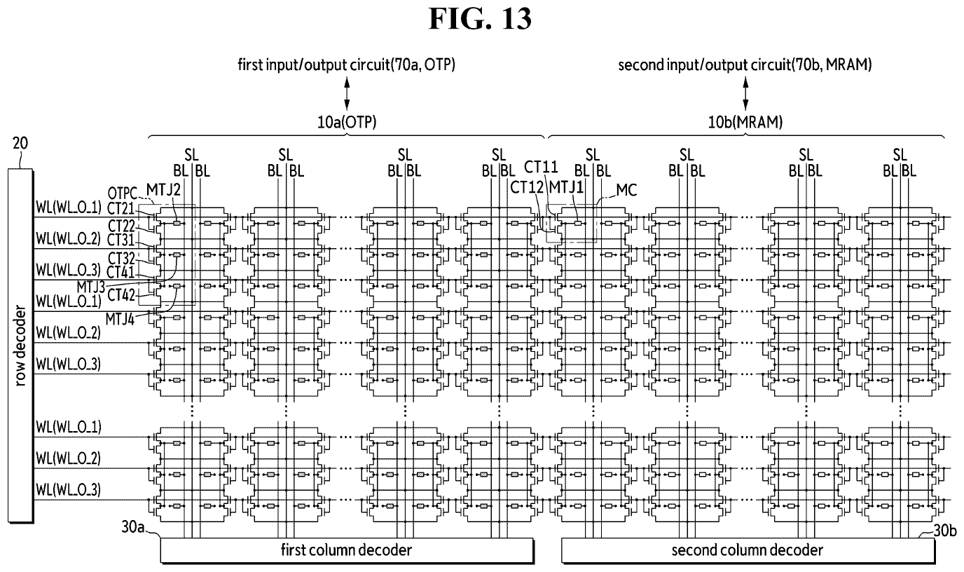

FIG. 13 is an exemplary circuit diagram illustrating a magnetic memory device according to some embodiments. For convenience of description, portions repeated with those described with reference to FIGS. 1 to 11 will be briefly described or omitted.

Referring to FIG. 13, in some embodiments, the OTP unit cells OTPC may be disposed in a memory cell array (e.g., a first memory cell array 10a) connected to a specific input/output circuit (e.g., a first input/output circuit 70a).

The memory cell array (10 of FIG. 1) may include a plurality of memory cell arrays. Each memory cell array may be connected to each of the input/output circuits and the column decoder.

For example, the memory cell array (10 of FIG. 1) may include a first memory cell array 10a and a second memory cell array 10b. The input/output circuit (70 of FIG. 1) may include a first input/output circuit 70a connected to the first memory cell array 10a and a second input/output circuit 70b connected to the second memory cell array 10b. The column decoder (30 of FIG. 1) may include a first column decoder 30a connected to the first memory cell array 10a and a second column decoder 30b connected to the second memory cell array 10b.

The first memory cell array 10a may include OTP unit cells OTPC, and the second memory cell array 10b may include memory unit cells MC. Only the OTP unit cells OTPC may be connected to the bit line BL of the first memory cell array 10a, and only the memory unit cells MC may be connected to the bit line BL of the second memory cell array 10b. The memory unit cells MC and the OTP unit cells OTPC may be connected to one word line WL. The memory unit cells MC and the OTP unit cells OTPC may be connected to different input/output circuits.

For example, the OTP unit cells OTPC may be disposed in the first memory cell array 10a disposed at the edge portion of the memory cell array (10 of FIG. 1).

FIG. 3 may be an exemplary cross-sectional view of a portion including three memory unit cells MC connected to one bit line of the second memory cell array 10b in FIG. 13, and FIGS. 4 to 7 may be exemplary cross-sectional views of a portion including one OTP unit cell OTPC connected to one bit line of the first memory cell array 10a in FIG. 13.

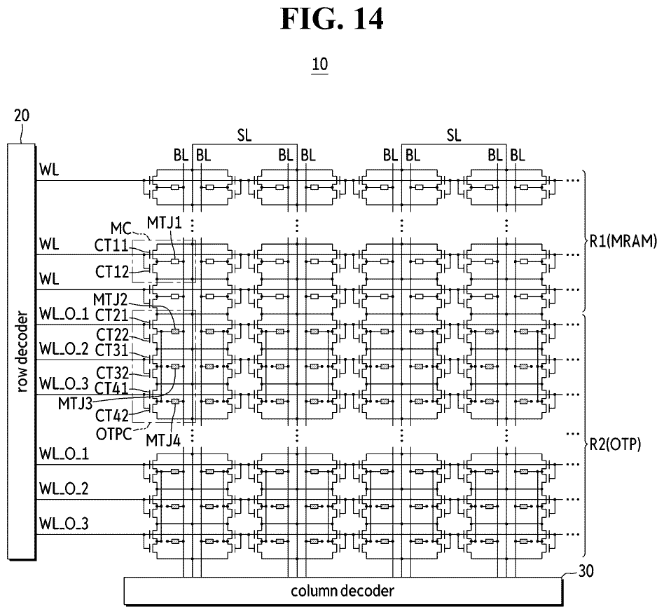

FIG. 14 is an exemplary circuit diagram illustrating a magnetic memory device according to some embodiments. For convenience of description, portions repeated with those described with reference to FIGS. 1 to 11 will be briefly described or omitted.

Referring to FIG. 14, in some embodiments, four columns of the memory unit cells MC may share one source line SL. For example, the memory unit cells MC constituting a first column, the memory unit cells MC constituting a second column, the memory unit cells MC constituting a third column and the memory unit cells MC constituting a fourth column may share one source line SL. The number of columns of the memory unit cells MC sharing one source line SL is not limited thereto, and five or more columns of the memory unit cells MC may share one source line SL.

The four columns of the OTP unit cells OTPC may share one source line SL. For example, the OTP unit cells OTPC constituting the first column, the OTP unit cells OTPC constituting the second column, the OTP unit cells OTPC constituting the third column and the OTP unit cells OTPC constituting the fourth column may share one source line SL. The number of columns of the OTP unit cells OTPC sharing one source line SL is not limited thereto, and five or more columns of the OTP unit cells OTPC may share one source line SL.

For example, the number of columns of the memory unit cells MC sharing one source line SL may be equal to the number of columns of the OTP unit cells OTPC sharing one source line SL.

FIG. 3 may be an exemplary cross-sectional view of a portion including three memory unit cells MC connected to one bit line in FIG. 14, and FIGS. 4 to 7 may be exemplary cross-sectional views of a portion including one OTP unit cell OTPC connected to one bit line in FIG. 14.

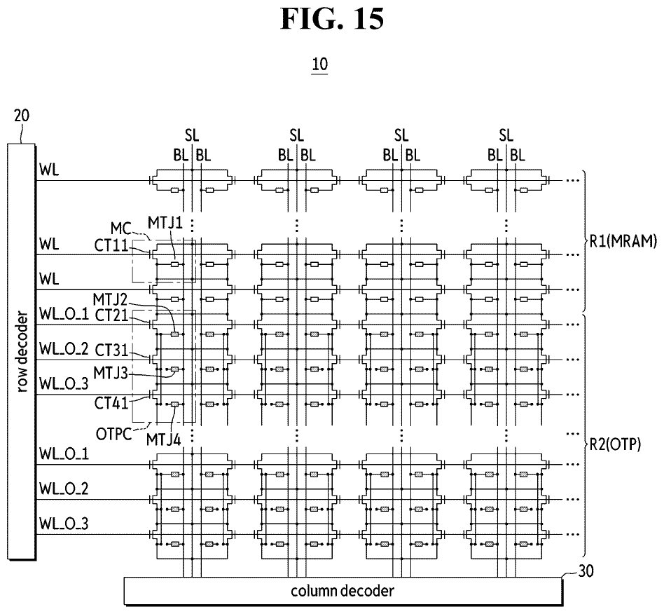

FIG. 15 is an exemplary circuit diagram illustrating a magnetic memory device according to some embodiments. For convenience of description, portions repeated with those described with reference to FIGS. 1 to 11 will be briefly described or omitted.

Referring to FIG. 15, in some embodiments, the memory unit cell MC may have a structure in which one cell transistor CT11 is connected to one magnetic tunnel junction element MTJ1. For example, the (1-2)th cell transistor CT12 of FIG. 2 may be omitted.

The OTP unit cell OTPC may have a structure in which three cell transistors CT21, CT31 and CT41 are connected to one magnetic tunnel junction element MTJ2. The second cell transistor CT21, the third cell transistor CT31 and the fourth cell transistor CT41 may be connected in parallel. For example, the (2-2)th cell transistor CT22, the (3-2)th cell transistor CT32 and the (4-2)th cell transistor CT42 of FIG. 2 may be omitted.

A pair of the second magnetic tunnel junction element MTJ2 and the second cell transistor CT21, a pair of the third magnetic tunnel junction element MTJ3 and the third cell transistor CT31 and a pair of the fourth magnetic tunnel junction element MTJ4 and the fourth cell transistor CT41 of the OTP unit cell OTPC may be respectively disposed in the memory cell array 10 to have the same repetition periodicity as a pair of the first magnetic tunnel junction element MTJ1 and the first cell transistor CT11 of the memory unit cell MC.

In the magnetic memory devices of FIGS. 12, 13 and 14, the (1-2)th cell transistor CT12, the (2-2)th cell transistor CT22, the (3-2)th cell transistor CT32 and the (4-2)th cell transistor CT42 may be omitted.

FIG. 3 may be an exemplary cross-sectional view of a portion including three memory unit cells MC connected to one bit line in FIG. 15, and FIGS. 4 to 7 may be exemplary cross-sectional views of a portion including one OTP unit cell OTPC connected to one bit line in FIG. 15.

The above-described magnetic memory device according to embodiments of the inventive concepts may be included in various electronic products including display devices, televisions, computers (e.g., laptops), phones (e.g., smartphones), severs, infotainment systems, or the like.

Although the embodiments according to the technical spirits of the present disclosure have been described with reference to the accompanying drawings, it will be apparent to those skilled in the art that the present disclosure can be fabricated in various forms without being limited to the above-described embodiments and may be embodied in other specific forms without departing from technical spirits and essential characteristics of the present disclosure. Thus, the above embodiments are to be considered in all respects as illustrative and not restrictive.

1. A magnetic memory device comprising:
a substrate; and
a memory cell array, which includes a memory unit cell and a one-time-programmable (OTP) unit cell, on the substrate,
wherein the memory unit cell includes:
a first magnetic tunnel junction element on the substrate, and
a wiring structure connecting the substrate with the first magnetic tunnel junction element, and
the OTP unit cell includes:
a connection wiring on the substrate,
a second magnetic tunnel junction element and a third magnetic tunnel junction element, which are spaced apart from each other on the connection wiring,
a first lower wiring structure and a second lower wiring structure, which connect the substrate with the connection wiring and spaced apart from each other, and
a first upper wiring structure connecting the connection wiring with the second magnetic tunnel junction element.

2. The magnetic memory device of claim 1, wherein the first lower wiring structure includes a first via connected to the substrate,
the second lower wiring structure includes a second via connected to the substrate, and
the connection wiring is connected to the first via and the second via.

3. The magnetic memory device of claim 1, further comprising a second upper wiring structure spaced apart from the connection wiring and connected to the third magnetic tunnel junction element between the connection wiring and the third magnetic tunnel junction element.

4. The magnetic memory device of claim 1, further comprising first and second sub-wiring structures between the connection wiring and the third magnetic tunnel junction element,
wherein the first sub-wiring structure is connected to the connection wiring, and
the second sub-wiring structure is connected to the third magnetic tunnel junction element and spaced apart from the first sub-wiring structure.

5. The magnetic memory device of claim 1, wherein the first upper wiring structure includes a lower electrode connecting the second magnetic tunnel junction element with the connection wiring, and
the third magnetic tunnel junction element and the connection wiring are spaced apart from each other.

6. The magnetic memory device of claim 1, wherein the OTP unit cell further includes:
a fourth magnetic tunnel junction element spaced apart from the second magnetic tunnel junction element and the third magnetic tunnel junction element on the connection wiring, and
a third lower wiring structure connecting the substrate with the connection wiring and spaced apart from the first lower wiring structure and the second lower wiring structure.

7. The magnetic memory device of claim 1, wherein the memory cell array includes a first memory cell array and a second memory cell array, which are connected to different input/output circuits,
the first memory cell array includes the memory unit cell, and
the second memory cell array includes the OTP unit cell.

8. The magnetic memory device of claim 1, wherein a width of the first magnetic tunnel junction element is greater than a width of the second magnetic tunnel junction element.

9. The magnetic memory device of claim 1, wherein a width of the first magnetic tunnel junction element is greater than a width of the second magnetic tunnel junction element and a width of the third magnetic tunnel junction element.

10. The magnetic memory device of claim 1, wherein the memory unit cell includes a first cell transistor electrically connected to the wiring structure on the substrate and including a first gate electrode and a first gate dielectric film,
the OTP unit cell includes a second cell transistor electrically connected to the first lower wiring structure on the substrate, including a second gate electrode and a second gate dielectric film, and
a width of the second gate electrode is smaller than a width of the first gate electrode.

11. The magnetic memory device of claim 1, further comprising a peripheral circuit electrically connected to the memory cell array,
wherein the memory unit cell and the OTP unit cell share the peripheral circuit.

12. (canceled)

13. (canceled)

14. A magnetic memory device comprising:
a memory unit cell including a first magnetic tunnel junction element connected to a first bit line and a first cell transistor connecting the first magnetic tunnel junction element with a first source line; and
a one-time-programmable (OTP) unit cell including second to fourth magnetic tunnel junction elements connected to a second bit line and second to fourth cell transistors connecting a second source line with the second magnetic tunnel junction element,
wherein the third and fourth magnetic tunnel junction elements are not connected to the second to fourth cell transistors.

15. The magnetic memory device of claim 14, wherein the first bit line and the second bit line are the same as each other, and the first source line and the second source line are the same as each other.

16. The magnetic memory device of claim 14, wherein the first bit line is different from the second bit line, and the first source line is different from the second source line.

17. The magnetic memory device of claim 14, wherein a threshold voltage of the second to fourth cell transistors is smaller than a threshold voltage of the first cell transistor.

18. The magnetic memory device of claim 14, wherein resistance of each of the second to fourth magnetic tunnel junction elements is greater than resistance of the first magnetic tunnel junction element.

19. The magnetic memory device of claim 14, wherein gates of the second to fourth cell transistors are connected to different word lines, respectively.

20. The magnetic memory device of claim 14, wherein the second to fourth cell transistors are configured to be turned on during a read operation of the OTP unit cell.

21. (canceled)

22. (canceled)

23. A magnetic memory device comprising:
a plurality of memory unit cells connected between a first bit line and a first source line;
a plurality of one-time-programmable (OTP) unit cells connected between a second bit line and a second source line; and
a peripheral circuit connected to the plurality of memory unit cells and the plurality of OTP unit cells,
wherein each of the plurality of memory unit cells includes a first magnetic tunnel junction element connected to the first bit line and a first cell transistor connecting the first magnetic tunnel junction element with the first source line,
each of the plurality of OTP unit cells includes second to fourth magnetic tunnel junction elements connected to the second bit line and second to fourth cell transistors connecting the second source line with the second magnetic tunnel junction element, and
the third and fourth magnetic tunnel junction elements are not connected to the second to fourth cell transistors.

24. The magnetic memory device of claim 23, wherein a gate of the first cell transistor is connected to a first word line,
a gate of the second cell transistor is connected to a second word line, and
a gate of the third cell transistor and a gate of the fourth cell transistor are connected to a third word line different from the second word line.

25-34. (canceled)
